(19) United States
(12) Patent Application Publication
(10) Pub. No.: US 2010/0175857 A1
(43) Pub. Date: Jul. 15, 2010

(54) MILLICHANNEL HEAT SINK, AND STACK AND APPARATUS USING THE SAME

(75) Inventors: William Dwight Gerstler, Niskayuna, NY (US); Joseph Lucian Smolenski, Slingerlands, NY (US); Richard Alfred Beaupre, Pittsfield, MA (US); Stephen Adam Solovitz, Portland, OR (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 12/354,386

(22) Filed: Jan. 15, 2009

(51) Int. Cl. H05K 7/20; F28D 15/00; F28F 3/12; F28F 13/06

(52) U.S. Cl. 165/104.31; 165/104.19; 165/104.33; 165/168; 165/133

(57) ABSTRACT

A cooling device comprises an upper surface configured to contact the baseplate, an inlet manifold configured to receive a coolant, an outlet manifold configured to exhaust the coolant, and at least one set of millichannels in the upper surface. The at least one set of the millichannels defines at least one heat sink region with at least one groove about one or more millichannels in the respective heat sink region with the groove configured to receive a seal. The at least one heat sink region establishes direct contact of the coolant with the baseplate, and the millichannels are configured to receive the coolant from the inlet manifold and to deliver the coolant to the outlet manifold. An apparatus and a stack are also presented.

### STATEMENT OF GOVERNMENT INTEREST

This invention may have been made with government support under contract number F33615-03-D-2352 awarded by the United States Air Force. The government may have certain rights in the invention.

### BACKGROUND

Power electronics refers to the application of solid-state electronics related to the control and conversion of electrical power. This conversion is typically performed by Silicon, Silicon Carbide, and Gallium Nitride devices that are packaged into power modules. One of the factors associated with the power modules is that they tend to generate heat. While the heat generated by the device is due to many factors, it generally relates to the fact that the device efficiency is always less than 100%, and the efficiency loss typically becomes heat. Unfortunately, device performance tends to erode with increased temperatures and at certain temperature thresholds the device is destroyed.

An additional factor for thermal management relates to the packaging of a number of devices in small footprints. The power density at which the devices, and thus the module can operate, therefore depends on the ability to remove this generated heat. For many applications, including military and commercial aviation power electronics, the highest possible power density is needed.

The most common form of the thermal management of power electronics is by heat sinks. Heat sinks operate by transferring the heat away from the heat source thereby maintaining a lower temperature of the source. There are various types of heat sinks known in the thermal management field including air cooled and liquid cooled devices.

One example of the thermal management of a power module includes the attachment of a heat sink with embedded tubes to provide liquid cooling of the power module. The heat sink is typically a metallic structure, such as aluminum or copper. The tubes are generally metallic as well, with copper being the most common material. Some substance in liquid form such as water is passed through the tubes, and subsequently passes through the tubes in the structure. Typical tube outside diameters (ODs) are ½″, ⅜″, and occasionally as small as ¼″. Due to turn radius and pressure limitations, there are usually no more than 4 to 6 tube passages per six-inch width.

The heat sink is typically coupled to the power module base with a thermal interface material (TIM) dispersed therebetween. The thermal interface material may comprise thermal greases, compliant thermal pads, or the like. Although a relatively good thermal contact is accomplished, the thermal interface material has certain thermal resistance, which is disadvantageous to heat exchange between the heat sink and the heated surface. The thermal interface material is a better thermal conductor than air, but still tends to be the largest single component of thermal resistance between the heat source and the liquid cooling.

One approach utilizes self-contained micro-channel heat sinks having micrometer-sized channels. However, in order to assure good thermal contact, thermal interface materials are still often employed between the millichannel heat sinks and the respective heated surfaces.

One implementation described in commonly assigned U.S. Pat. No. 7,353,859, incorporated by reference herein for all purposes, provides for a system that delivers cooling fluid to the backside of the substrate with a metallurgical mounting.

Despite the advancements and improvements, there is a continued need for new and improved heat sinks, and stacks and apparatuses using the heat sinks.

### BRIEF DESCRIPTION

A cooling device for an electronic module mounted on a baseplate is provided in accordance with one embodiment of the invention. The cooling device comprises an upper surface configured to contact the baseplate, an inlet manifold configured to receive a coolant, an outlet manifold configured to exhaust the coolant, and at least one set of millichannels in the upper surface. The at least one set of millichannels defines at least one heat sink region with at least one groove about one or more millichannels in the respective heat sink region with the groove configured to receive a seal. The at least one heat sink region establishes direct contact of the coolant with the baseplate, and the millichannels are configured to receive the coolant from the inlet manifold and to deliver the coolant to the outlet manifold.

A stack for cooling an electronic device is provided in accordance with another embodiment of the invention. The stack comprises a heat sink, a baseplate configured to be mated to the upper surface of the heat sink, and a substrate disposed on the baseplate and configured to be coupled to the electronic device. The heat sink comprises an upper surface, an inlet manifold configured to receive a coolant, an outlet manifold configured to exhaust the coolant, and a plurality of millichannels recessed downwardly from the upper surface. The millichannels defines a region with a groove about the region, and are configured to receive the coolant from the inlet manifold and to deliver the coolant to the outlet manifold. A seal is disposed in the groove.

An embodiment of the invention further provides an apparatus. The apparatus comprises at least one heat sink. Each heat sink comprises a substantially planar member with at least one upper surface, an inlet manifold configured to receive a coolant, an outlet manifold configured to exhaust the coolant, a plurality of millichannels on the upper surface and configured to receive the coolant from the inlet manifold and to deliver the coolant to the outlet manifold, and a groove about the millichannels with a seal in the groove. The apparatus further comprises at least one electronic module configured to mate with the at least one upper surface and forming a liquid tight seal.

### BRIEF DESCRIPTION OF THE DRAWINGS

The above and other aspects, features, and advantages of the present disclosure will become more apparent in light of the following detailed description when taken in conjunction with the accompanying drawings in which:

FIG. 1 is a schematic diagram of an apparatus comprising an electronic module and a heat sink in accordance with one embodiment of the invention;

FIG. 2 is a schematic diagram of an exemplary electronic module in accordance with one embodiment of the invention;

FIG. 3 is a schematic diagram of an exemplary stack comprising the heat sink, a baseplate, and a substrate in accordance with one embodiment of the invention;

FIG. 4 is a schematic diagram of the heat sink in accordance with another embodiment of the invention;

FIG. 5 is a schematic diagram of an integrated array of the heat sinks shown in FIG. 3;

FIG. 6 is a cross sectional view of the assembly of heat sinks taken along a line 6-6 shown in FIG. 5 in accordance with one embodiment of the invention;

FIG. 7 is a cross sectional view of the assembly of heat sinks taken along a line 7-7 shown in FIG. 5 in accordance with another embodiment of the invention; and

FIG. 8 is an enlarged schematic diagram of a millichannel in accordance with one embodiment of the invention.

### DETAILED DESCRIPTION

Various embodiments of the present disclosure will be described hereinbelow with reference to the accompanying drawings. This invention relates generally to heat sinks, and stacks and apparatuses using the heat sinks. More particularly, the invention relates to millichannel heat sinks, and stacks and apparatuses using the millichannel heat sinks. As used herein, the millichannel is referring to the main cooling channel's width and height being on the order of millimeters in each dimension.

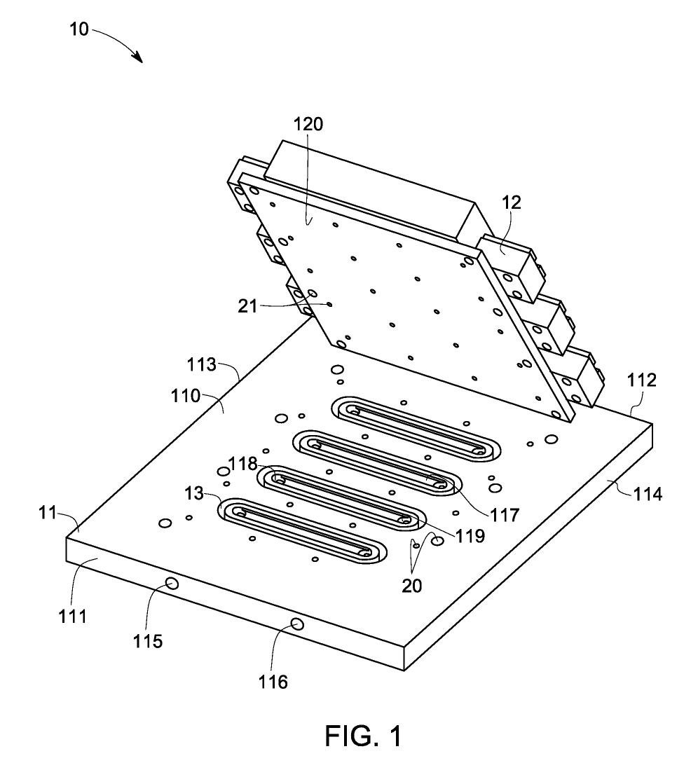

As illustrated in FIG. 1, the cooling system 10 comprises a cooling device (heat sink) 11 and an electronic module 12 disposed on a baseplate 120 and configured to be disposed on the heat sink 11. The electronic module in one embodiment is standardized such as commercial off the shelf (COTS) so that the shape, holes and features of the module 12 are matched to the baseplate 120. Additionally, the heat sink 11 can also be standardized so that the shape, holes and features of heat sink 11 are matched to the baseplate 120.

In the illustrated embodiment, the heat sink 11 is in a rectangular shape, and comprises an upper surface 110, a first side surface 111, a second side surface 112 opposite to the first side surface 111, a third side surface 113, and a fourth side surface 114 opposite to the third side surface 113. It should be noted that the exemplary heat sink 11 in FIG. 1 is illustrative, and the heat sink 11 may comprise other shapes, such as circular, triangular or other polygonal shapes.

In embodiments of the invention, the heat sink 11 is configured to cool the electronic module 12. Therefore, the heat sink 11 may comprise at least one thermally conductive material, non-limiting examples of which may include copper, aluminum, nickel, molybdenum, titanium, and alloys thereof. In some examples, the heat sink 11 may comprise at least one thermally conductive material, non-limiting examples of which may include metal matrix composites such as aluminum silicon carbide (AlSiC), aluminum graphite, and copper graphite. In other examples, the heat sink 11 may comprise at least one thermally conductive material, non-limiting examples of which may include ceramics such as aluminum oxide and silicon nitride ceramic. Alternatively, the heat sink 11 may comprise at least one thermoplastic material. In the illustrated embodiment, the heat sink 11 comprises aluminum.

In the exemplary embodiment, the heat sink 11 comprises an inlet manifold 115 and an outlet manifold 116, which in this example are both recessed into the heat sink 11 from the first side surface 111. In non-limiting examples, both the inlet manifold 115 and the outlet manifold 116 may be recessed into the heat sink 111 from one of the second, third and fourth side surfaces 112-114. Alternatively, the inlet manifold 115 and the outlet manifold 116 may be recessed into the heat sink 111 from different side surfaces, respectively. In embodiments of the invention, the inlet manifold 115 is configured to receive a coolant and the outlet manifold 116 is configured to exhaust the coolant. Non-limiting examples of the coolant comprise de-ionized water and other non-electrically conductive liquids.

For the exemplary arrangement in FIG. 1, the heat sink 11 further comprises a plurality of millichannels 117 defining a heat sink region (not labeled) and arranged parallel to each other. Alternatively, in certain applications, the millichannels 117 may be arranged in different patterns such as angular, arc, zigzag and other patterns depending upon the design criteria. In certain examples, the millichannel may refer to a channel with a hydraulic diameter between about 0.3 mm and 5 mm. In embodiments of the invention, each of the millichannels 117 are recessed downwardly from the upper surface 110 of the heat sink 11 to form trenches in the upper surface 110. Thus, the millichannels 117 may be open at the upper surface 110 of the heat sink 11. Accordingly, when the electronic module 12 and the baseplate 120 are disposed on the heat sink 11, the coolant in the millichannel 117 can contact directly with the baseplate 120 to cool the electronic module 12. Additionally, in the illustrated embodiment, the millichannels 117 extends on the upper surface 110 along a direction from the third side surface 113 to the fourth side surface 114. In some examples, each millichannel 117 may extend along other directions, non-limiting examples of which may include a direction from the first side surface 111 to the second side surface 112.

In the exemplary embodiment, each millichannel 117 comprises an inlet 118 configured to be in fluid communication with the inlet manifold 115 and an outlet 119 configured to be in fluid communication with the outlet manifold 116. In one non-limiting example, the inlet 118 and the outlet 119 may be disposed to be in fluid communication with the respective manifolds 115, 116. Thus, the millichannels 117 can receive the coolant from the inlet manifold 115 and deliver the coolant to the outlet manifold 116. According to more particular embodiments, the millichannels 117 and the manifolds 115, 116 are configured to deliver the coolant uniformly. Additionally, in certain examples, the heat sink 11 may comprise two or more inlet manifolds 115 and/or two or more outlet manifolds 116 in fluid communication with the respective inlets and outlets. The multiple manifolds allow for non-uniform coolant delivery.

In certain embodiments of the invention, the millichannel 117 may comprise a U-shaped cross section. Non-limiting examples of the cross sections of the millichannel 117 may further include circular, triangular, trapezoidal, and square/rectangular cross-sections. And the millichannels 117 may be cast, machined, or etched, and may be smooth or rough. The rough millichannels may have relatively larger surface area to enhance turbulence of the coolant so as to augment thermal transfer therein. In non-limiting examples, the millichannels may employ features such as dimples, bumps, or the like therein to increase the roughness thereof. Similarly to the millichannels 117, the manifolds 115, 116 may also have a variety of cross-sectional shapes, including but not limited to, round, circular, triangular, trapezoidal, and square/rectangular cross-sections. The channel shape is selected based on the applications and manufacturing constraints and affects the applicable manufacturing methods, as well as coolant flow.

For some embodiments, the manifolds 115 and 116 may have relatively larger diameters than the millichannels 117. In one non-limiting example, the width of the millichannel is in a range of about 0.5 mm to about 3.0 mm, the depth of the millichannel is in a range of about 0.5 mm to about 3.0 mm, and the length of the millichannel is in a range of about 10 mm to 100 mm.

For the exemplary arrangement in FIG. 1, the electronic module 12 comprises a baseplate 120 configured to contact the millichannels 117 directly to perform heat exchange therebetween. In certain embodiments, similar to the heat sink 11, the baseplate 120 may also comprise at least one thermally conductive material, non-limiting examples of which may include copper, aluminum, nickel, molybdenum, titanium, alloys thereof. In some examples, the baseplate 120 may also comprise at least one thermally conductive material, non-limiting examples of which may include thermo pyrolytic graphite (TPG). In other examples, the baseplate 120 may also comprise at least one thermally conductive material, non-limiting examples of which may include metal matrix composites such as aluminum silicon carbide (AlSiC), aluminum graphite, and copper graphite. Alternatively, the baseplate 120 may also comprise at least one thermally conductive material, non-limiting examples of which may include ceramics such as aluminum oxide and silicon nitride ceramic. Additionally, the baseplate 120 may also include at least one thermoplastic material. In the illustrated embodiment, the baseplate 120 comprises copper.

In one non-limiting example, the heat sink 11 and the baseplate 120 may define mounting holes 20, 21 (shown in FIG. 1), respectively. Additionally, for the exemplary arrangement in FIG. 1, the apparatus 10 may further comprises a plurality of grooves 13 and each groove 13 is disposed around one millichannel 117. The apparatus 10 may comprise a plurality of seals (not shown) to be received in the respective grooves 13 to prevent the coolant in the corresponding millichannel 117 from leakage and provide a liquid tight seal. In some examples, the seal may comprise a gasket, an o-ring, or any other type of seal, such as metallurgical bonding with a similar function.

In operation according to one embodiment, the seals, such as O-rings (not shown), are placed in the grooves 13 and the basplate 120 is secured to the heat sink 11 by fasteners (not shown) that engage the holes 20, 21. The seals provide for liquid tight compartments around each millichannel 117 thereby allowing direct coolant contact with the basplate 120 without the use if interfering thermal interface materials. The fasteners can be nuts and bolts or other fasteners known in the field.

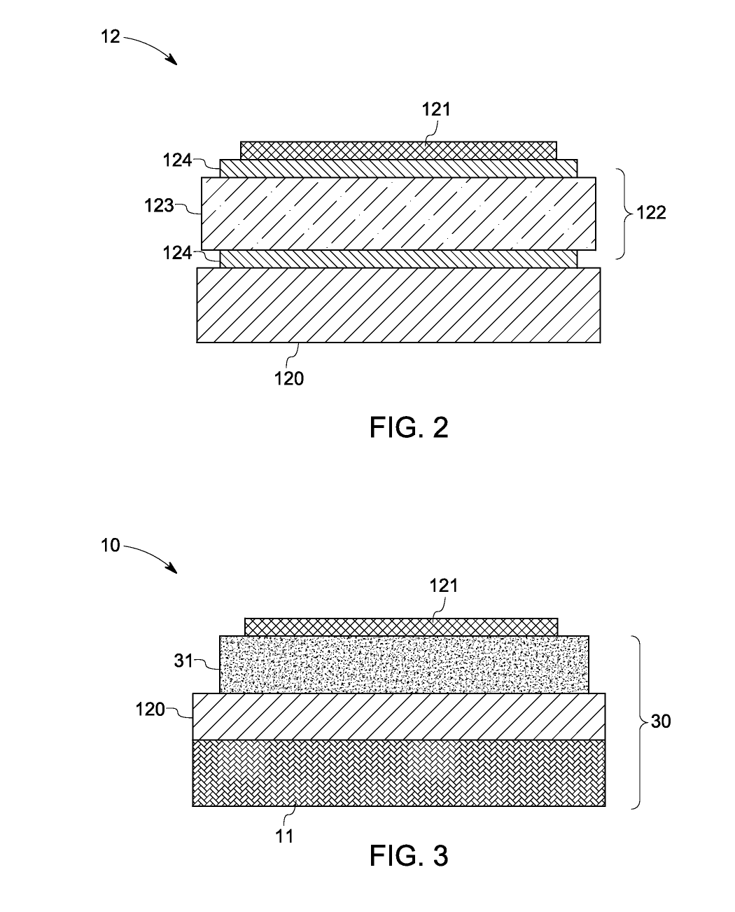

FIG. 2 illustrates a schematic diagram of one exemplary electronic module 12 in accordance with one embodiment of the invention. As illustrated in FIG. 2, the electronic module 12 comprises the baseplate 120 and a heat source 121, such as an electronic device producing heat when operating. For some embodiments of the invention, non-limiting examples of the electronic device 121 may include Insulated Gate Bipolar Transistors (IGBT), Metal Oxide Semiconductor Field Effect Transistors (MOSFET), Diodes, Metal Semiconductor Field Effect Transistors (MESFET), and High Electron Mobility Transistors (HEMT). The embodiments of the invention may find applications to the electronic device manufactured from a variety of semiconductors, non-limiting examples of which include silicon (Si), silicon carbide (SiC), gallium nitride (GaN), and gallium arsenide (GaAs).

In certain embodiments of the invention, the baseplate 120 may be thermally and electrically conductive. Accordingly, as shown in FIG. 2, the electronic module 12 further comprises at least one layer 122 between the baseplate 120 and the electronic device 121 to avoid short circuit and to perform heat exchange therebetween. In embodiments of the invention, the at least one layer 122 can be served as a substrate for connecting the baseplate 120 and the heat source 121.

For the exemplary arrangement in FIG. 2, the substrate 122 at least comprises an electrically isolating and thermally conductive layer, such as a ceramic layer 123. In order to attach the ceramic layer 123 to the baseplate 120 and the heat source 121 stably and securely, the substrate 122 may further comprise conductive layers, such as copper layers 124 bonded to an upper surface and a lower surface (not labeled) of the ceramic layer 123. That is, the substrate 122 may have either a direct bonded copper (DBC), or an active metal braze (AMB) structure. The DBC and AMB refer to processes which copper layers are directly bonded to a ceramic layer. Alternatively, the copper layer 124 on the lower surface may not be employed, such that the baseplate 120 may be bonded directly to the lower surface of the ceramic layer 123. Similar to the DBC and AMB, the substrate 122 may have direct bond aluminum (DBA) structure. DBA refers to a process which aluminum layers are directly bonded to a ceramic layer.

Non-limiting examples of the ceramic layer 123 may comprise aluminum oxide (AL₂O₃), aluminum nitride (AIN), beryllium oxide (BeO), and silicon nitride (Si₃N₄). Both the DBC and the AMB may be convenient structures for the substrate 122, and the use of the conductive material (in this case, copper) on the ceramic layer 123 may provide thermal and mechanical stability. Alternatively, the conductive layer can comprise other materials, such as gold, silver, and alloys thereof according to different applications. For the arrangement in FIG. 2, the substrate 122 can be attached to the baseplate 120 and the heat source 121 using a number of techniques, including but not limited to, brazing, bonding, diffusion bonding, soldering, or pressure contact such as clamping, which provides a simple assembly process, which reduces the overall cost of the apparatus 10.

Accordingly, for the exemplary arrangements in FIGS. 1-2, when assembled to work, the heat from the heat source 121 passes downwardly through the substrate 122 to reach the baseplate 120, and the coolant in the heat sink 11 contacts directly with the baseplate 120 to perform the heat exchange therebetween so as to transfer the heat away from the heat source 121. The gaskets in the grooves provide the liquid tight seal about the millichannels 117.

It should be noted that the exemplary arrangement in FIG. 2 is illustrative, and the invention is by no means limited by this arrangement. In some non-limiting examples, the electronic modules 12 are available and generally are provided as packages by manufacturers. Accordingly, the material between the baseplate 120 and the heat source 121 may not need to be determined. In other examples, when the baseplate 120 comprises thermally and electrically conductive material, at least one electrically isolating and thermally conductive layer, which may act as a substrate similar to the substrate 122, may be disposed between the baseplate 120 and the electronic device 121 to avoid short circuit and to perform the heat exchange therebetween.

In other non-limiting examples, as illustrated in FIG. 3, the heat sink 11, the baseplate 120, and a substrate 31 similar to the substrate 122 together may first form a stack 30. And then, the heat source 121 (shown in FIG. 1) may be assembled onto the stack by some known methods, such as bonding, soldering to form the apparatus 10.

FIG. 4 illustrates a schematic diagram of a heat sink 40 in accordance with another embodiment of the invention. As illustrated in FIG. 4, similar to the heat sink 11, the heat sink 40 comprises at least one inlet manifold 41, at least one outlet manifold 42, a plurality of millichannels 43 recessed downwardly from an upper surface 44 thereof. The inlet and outlet manifolds 41, 42 may be recessed into the heat sink 40 from the same or different side surface(s) (not labeled). The millichannels 43 may be arranged parallel to each other or in other patterns, and comprise inlets 430 and outlets 431 in fluid communication with the inlet and outlet manifolds 41-42 respectively for the coolant passing in and out. Additionally, the material of the heat sink 40 may also be similar to the material of the heat sink 11. In some examples, similar to the heat sink 11, the heat sink 44 may define mounting holes 45 for cooperating with corresponding holes 21 of the baseplate 120 of the electronic module 12 (shown in FIG. 1). Thus, the electronic module 12 can also be assembled onto the heat sink 40, such that the heat sink 40 cools the electronic module 12. In certain embodiments, tubes 46, 47 may be provided to be in fluid communication with the inlet and outlet manifolds 41, 42 respectively, such that a pump, a heat exchanger, and/or a coolant source (not shown) may be in fluid communication with the manifolds by using the tubes.

For the embodiment in FIG. 4, the heat sink 40 further is formed with a groove 48 recessed downwardly from the upper surface 44 thereof and disposed around the millichannels 43 for receiving a seal, such as an O-ring. Thus, before the electronic module 12 is assembled onto the heat sink 44, the O-ring (not shown) is disposed in the 0-shaped groove 48 to prevent the coolant from leaking out of the assembly of the heat sink 44 and the electronic module 12.

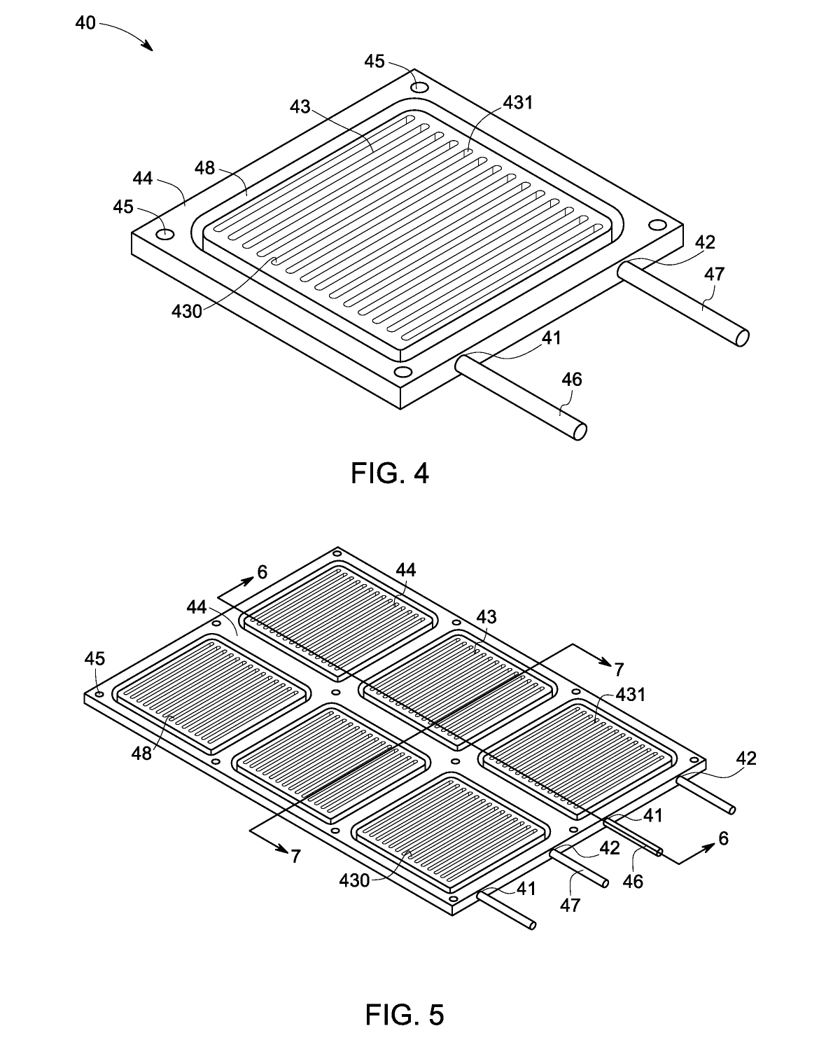

In certain embodiments of the invention, the apparatus 10 may comprise more than one heat sink 11 or 44 to cool more than one electronic module 12. One can take the heat sink 44 as an example. FIG. 5 illustrates a schematic diagram of an assembly of the heat sinks 44 shown in FIG. 3. As illustrated in FIG. 5, the apparatus 10 comprises a set of six heat sinks 44 arranged in two rows, two inlet manifolds 41, and two outlet manifolds 42 in fluid communication with the inlets 430 and the outlets 431 of the millichannels 43 in the respective rows, respectively. In some non-limiting examples, the apparatus 10 may comprise more than two inlet manifolds 41 and more than two outlet manifolds 42. Additionally, the apparatus 10 further comprises a plurality of grooves 48, each is disposed around the millichannels 43 of one heat sink 44 for receiving one gasket therein. Similar to the assembly of the heat sinks 44, an assembly (not shown) of the heat sinks 11 can be easily implemented.

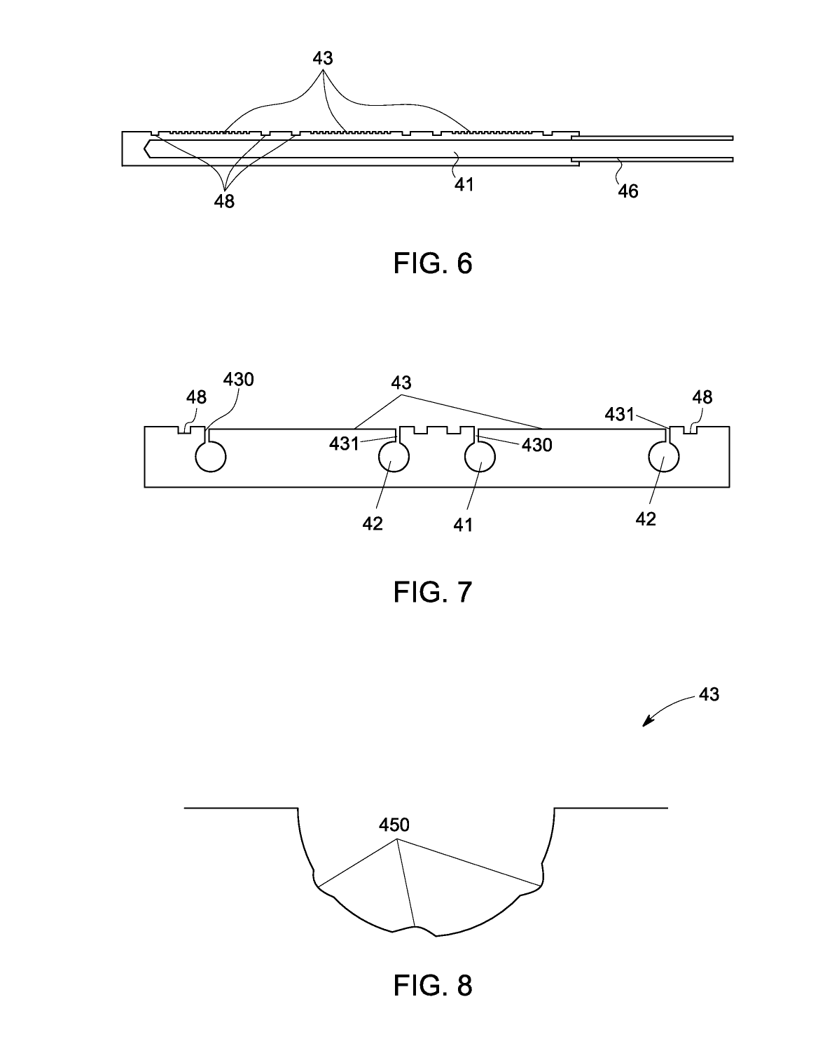

FIG. 6 illustrates a cross sectional perspective along a line 6-6 shown in FIG. 5. As illustrated in FIG. 6, the millichannels 43 are recessed downwardly from the upper surface of the heat sinks 44 to provide the liquid cooling pathways and contact to the baseplate 120. The grooves 48 are disposed about the respective set of the millichannels 43 and configured to receive O-rings for liquid tight seal and defining heat sink regions. FIG. 7 illustrates a cross section perspective along a line 7-7 shown in FIG. 5. Referring to FIG. 7, the cross sectional perspective illustrates the inlet and outlet manifolds 40, 41 in fluid communication with the inlets and outlets 430, 431 to conduct the liquid ingress to and egress from the millichannels 43. The O-ring grooves 48 mate with corresponding O-rings (not shown) to create a liquid tight seal and allow for the direct contact of the coolant to the baseplate 120 (shown in FIG. 1). The millichannels 43, inlet/outlet manifolds 40, 41 and/or inlets/outlets 430, 431 in one example includes features 450 (shown in FIG. 8) such as dimples, bumps, or the like therein to increase the roughness thereof. As illustrated in FIG. 8, the features 450 are defined at side surfaces and bottom surfaces of the millichannels 43. It should be noted that the exemplary millichannel 43 has a circular cross section, but in some non-limiting examples, the millichannel 43 may have a variety of cross sections. And the millichannel 43 may define bumps, dimples, or combination thereof.

According to one embodiment, each of the heat sinks is aligned with the corresponding electronic device that is the heat source. In a further aspect, devices that generate more heat can be optimally managed by design criteria of the heat sinks and/or the system management. For example, the size and number of the millichannels can be tailored for the cooling requirements and heat sinks requiring more thermal dissipation can have deeper millichannels and would therefore carry more liquid. Similarly, the system controlling the liquid flow can create a greater flow through the heat sinks requiring more cooling capacity. Thermal sensors (not shown) can be used to assist in the thermal management and flow capacity.

While the disclosure has been illustrated and described in typical embodiments, it is not intended to be limited to the details shown, since various modifications and substitutions can be made without departing in any way from the spirit of the present disclosure. As such, further modifications and equivalents of the disclosure herein disclosed may occur to persons skilled in the art using no more than routine experimentation, and all such modifications and equivalents are believed to be within the spirit and scope of the disclosure as defined by the following claims.

What is claimed is:

1. A cooling device for an electronic module mounted on a baseplate, the cooling device comprising:
an upper surface configured to contact the baseplate;
an inlet manifold configured to receive a coolant;
an outlet manifold configured to exhaust the coolant; and
at least one set of millichannels in the upper surface defining at least one heat sink region with at least one groove about one or more millichannels in the respective heat sink region with the groove configured to receive a seal, wherein the at least one heat sink region establishes direct contact of the coolant with the baseplate, and wherein the millichannels are configured to receive the coolant from the inlet manifold and to deliver the coolant to the outlet manifold.

2. The device of claim 1, wherein each of the millichannels comprises an inlet and an outlet in fluid communication with the inlet manifold and the outlet manifold, respectively.

3. The device of claim 2, wherein the inlet and outlet extend downwardly to communicate fluidly with the inlet and outlet manifolds.

4. The device of claim 1, further comprising at least one side surface, and wherein the inlet and outlet manifolds extend into the heat sink from the at least one side surface.

5. The device of claim 1, wherein the device comprises a plurality of heat sink regions each with the plurality of millichannels and corresponding grooves.

6. The device of claim 1, wherein the seal comprises at least one of an O-ring, a gasket, and metallurgical bonding.

7. The device of claim 1, further comprising at least one of one or more dimples and one or more bumps disposed in the millichannels and configured to increase roughness of the millichannels.

8. The device of claim 1, wherein each of the millichannels comprises at least one of circular, triangular, trapezoidal, and rectangular cross-sections.

9. The device of claim 1, wherein the cooling device comprises at least one thermally conductive material, and wherein the at least one thermally conductive material comprises one or more of copper, aluminum, nickel, molybdenum, titanium, copper alloys, nickel alloys, molybdenum alloys, and titanium alloys.

10. The device of claim 1, wherein the cooling device comprises at least one thermally conductive material, and wherein the at least one thermally conductive material comprises one or more of aluminum silicon carbide, aluminum graphite and copper graphite.

11. The device of claim 1, wherein the cooling device comprises at least one thermally conductive material, and wherein the at least one thermally conductive material comprises one or more of aluminum oxide and silicon nitride ceramic.

12. The device of claim 1, wherein the cooling device comprises at least one thermal plastic material.

13. The device of claim 1, wherein the baseplate is secured to the cooling device by one or more fasteners.

14. The device of claim 13, wherein the fasteners are nuts and bolts.

15. A stack for cooling an electronic device, comprising:
a heat sink comprising:
an upper surface,
an inlet manifold configured to receive a coolant,
an outlet manifold configured to exhaust the coolant, and
a plurality of millichannels recessed downwardly from the upper surface and defining a region with a groove about the region, wherein a seal is disposed in the groove, and wherein the millichannels are configured to receive the coolant from the inlet manifold and to deliver the coolant to the outlet manifold;
a baseplate configured to be mated to the upper surface of the heat sink; and
a substrate disposed on the baseplate and configured to be coupled to the electronic device.

16. The stack of claim 15, wherein each of the millichannels comprises an inlet and an outlet extending downwardly to communicate fluidly with the inlet manifold and the outlet manifold, respectively.

17. The stack of claim 15, wherein each of the millichannels comprises at least one of circular, triangular, trapezoidal, and rectangular cross-sections.

18. The stack of claim 15, wherein at least one of the heat sink and the baseplate comprises at least one thermally conductive material, and wherein the at least one thermally conductive material comprises one or more of copper, aluminum, nickel, molybdenum, titanium, copper alloys, nickel alloys, molybdenum alloys, and titanium alloys.

19. The stack of claim 15, wherein the heat sink and the baseplate comprises at least one thermally conductive material, and wherein the at least one thermally conductive material comprises one or more of aluminum silicon carbide, aluminum graphite, and copper graphite.

20. The device of claim 15, wherein the heat sink and the baseplate comprises at least one thermally conductive material, and wherein the at least one thermally conductive material comprises one or more of aluminum oxide and silicon nitride ceramic.

21. The stack of claim 15, wherein the heat sink and the baseplate comprises at least one thermal plastic material.

22. An apparatus, comprising:
at least one heat sink, each heat sink comprising:
a substantially planar member with at least one upper surface,
an inlet manifold configured to receive a coolant,
an outlet manifold configured to exhaust the coolant,
a plurality of millichannels on the upper surface and configured to receive the coolant from the inlet manifold and to deliver the coolant to the outlet manifold, and
a groove about the millichannels with a seal in the groove; and
at least one electronic module configured to mate with the at least one upper surface and forming a liquid tight seal.

23. The apparatus of claim 22, wherein the electronic module comprises a baseplate, an electronic device, and a substrate disposed between the baseplate and the electronic device.
